(19) United States
(12) Patent Application Publication
(10) Pub. No.: US 2012/0091472 A1
(43) Pub. Date: Apr. 19, 2012

(54) SILICON CARBIDE SUBSTRATE

(75) Inventors: Makoto Sasaki, Hyogo (JP); Shin Harada, Osaka (JP); Kyoko Okita, Hyogo (JP); Tomihito Miyazaki, Osaka (JP)

(73) Assignee: SUMITOMO ELECTRIC INDUSTRIES, LTD., Osaka-shi (JP)

(21) Appl. No.: 13/377,360

(22) PCT Filed: Feb. 23, 2011
(86) PCT No.: PCT/JP2011/054009

§ 371 Date: Dec. 9, 2011

(30) Foreign Application Priority Data
Apr. 12, 2010 (JP) 2010-091528

(51) Int. Cl. H01L 29/24

(52) U.S. Cl. 257/77; 257/E29.104

(57) ABSTRACT

A first circular surface is provided with a first notch portion having a first shape. A second circular surface is opposite to the first circular surface and is provided with a second notch portion having a second shape. A side surface connects the first circular surface and the second circular surface to each other. The first notch portion and the second notch portion are opposite to each other. The side surface has a first depression connecting the first notch portion and the second notch portion to each other.

### TECHNICAL FIELD

The present invention relates to a silicon carbide substrate, in particular, a silicon carbide substrate having a single-crystal structure.

### BACKGROUND ART

Silicon carbide has some characteristics more excellent than those of silicon, such as large band gap, large maximum dielectric breakdown electric field, and large heat conductivity. Hence, it has been considered to manufacture a semiconductor device using a silicon carbide substrate. For example, Non-Patent Literature 1, Hiroshi YANO et al., “High Channel Mobility in Inversion Layer of SiC MOSFETs for Power Switching Transistors”, Jpn. J. Appl. Phys. Vol. 39 (2000) pp. 2008-2011, discloses a MOSFET (Metal Oxide Semiconductor Field Effect Transistor). Further, this literature discloses that when a MOSFET is fabricated on the (11-20) plane of the silicon carbide substrate, a drain current in the <1-100> direction becomes three times larger in magnitude than a drain current in the <0001> direction. Hence, when manufacturing a semiconductor device using such a silicon carbide substrate, it is necessary to know orientation in the in-plane direction of the silicon carbide substrate. In order to know the crystal orientation of the silicon carbide substrate, Patent Literature 1 (Japanese Patent Laying-Open No. 2009-081290) discloses a method for forming an orientation flat.

Further, in order to efficiently manufacture a semiconductor device, the substrate is required to have a large size to some extent. According to Patent Literature 2 (U.S. Pat. No. 7,314,520), a silicon carbide substrate of 76 mm (3 inches) or larger can be manufactured.

### CITATION LIST

### Patent Literature

PTL 1: Japanese Patent Laying-Open No. 2009-081290

PTL 2: U.S. Pat. No. 7,314,520

### Non Patent Literature

NPL 1: Hiroshi YANO et al., “High Channel Mobility in Inversion Layer of SiC MOSFETs for Power Switching Transistors”, Jpn. J. Appl. Phys. Vol. 39 (2000) pp. 2008-2011

### SUMMARY OF INVENTION

### Technical Problem

As a result of examining methods for manufacturing a silicon carbide substrate, the present inventors have found a method by which a silicon carbide substrate having a size of 150 mm (6 inches) or greater can be industrially manufactured. When forming an orientation flat in such a large silicon carbide substrate, a required amount of grinding becomes large due to the large size of the substrate. However, silicon carbide is harder than silicon. Hence, it is not easy to grind it for a large amount.

The present invention has been made in view of the foregoing problem and has its object to provide a silicon carbide substrate allowing for indication of a crystal orientation and readily manufactured.

### Solution to Problem

A silicon carbide substrate of the present invention has a single-crystal structure, and includes first and second circular surfaces and a side surface. The first circular surface is provided with a first notch portion having a first shape. The second circular surface is opposite to the first circular surface and is provided with a second notch portion having a second shape. The side surface connects the first and second circular surfaces to each other. The first and second notch portions are opposite to each other. The side surface has a first depression connecting the first and second notch portions to each other.

Preferably, the silicon carbide substrate has asymmetry for given turnover of the silicon carbide substrate. In this way, the front side and backside of the silicon carbide substrate can be distinguished from each other.

Preferably, the first circular surface includes a third notch portion having a third shape different from the first shape. Further, the second circular surface includes a fourth notch portion having a fourth shape different from the second shape. The third and fourth notch portions are opposite to each other. The side surface has a second depression connecting the third and fourth notch portions.

Preferably, the first depression has asymmetry for the turnover.

Preferably, the first and second shapes are different from each other.

Preferably, the first and second shapes are the same and have asymmetry for the turnover.

Preferably, the first circular surface has a surface roughness different from that of the second circular surface. Accordingly, the front side and backside of the silicon carbide substrate can be distinguished from each other.

Preferably, one of the first and second circular surfaces has a surface roughness Ra less than 10 nm and the other thereof has a surface roughness Ra equal to or greater than 10 nm. Surface roughness Ra is determined by measurement for a square-shaped region having sides of 10 μm using an atomic force microscope (AFM).

Preferably, each of the first and second circular surfaces has a diameter equal to or greater than 15 cm.

Preferably, the single-crystal structure has hexagonal crystal. The first notch portion is positioned on an orthogonal projection, to the first circular surface, of an axis extending from a center of the first circular surface in one of a <11-20> direction and a <1-100> direction.

Preferably, the silicon carbide substrate has a micro pipe density of 10/cm² or smaller.

Preferably, the silicon carbide substrate has an etch-pit density of 10000/cm² or smaller.

Preferably, the silicon carbide substrate has a warpage of 30 μm or smaller.

Preferably, the single-crystal structure has hexagonal crystal. The first circular surface has an off angle of not less than 50° and not more than 65° relative to a {0001} plane. More preferably, one of the following first and second conditions is satisfied.

First, the off angle has an off orientation falling with a range of ±5° or smaller relative to a <01-10> direction. Preferably, the first circular surface has an off angle of not less than −3° and not more than +5° relative to a {03-38} plane in the <01-10>direction. More preferably, the first circular surface has an off angle of not less than −3° and not more than +5° relative to a {03-38} plane in the <01-10> direction. Second, preferably, the off angle has an off orientation falling within a range of ±5° or smaller relative to a <11-20> direction.

Here, the (0001) plane of single-crystal silicon carbide of hexagonal crystal is defined as the silicon plane whereas the (000-1) plane is defined as the carbon plane. Further, the “off angle relative to the {03-38} plane in the <01-10> direction” refers to an angle formed by an orthogonal projection of a normal line of the above-described first circular surface to a flat plane defined by the <01-10> direction and the <0001>direction serving as a reference for the above-described off orientation, and a normal line of the {03-38} plane. The sign of positive value corresponds to a case where the orthogonal projection approaches in parallel with the <01-10> direction whereas the sign of negative value corresponds to a case where the orthogonal projection approaches in parallel with the <0001> direction. Meanwhile, the “off angle relative to the (0-33-8) plane in the <01-10> direction” refers to an angle formed by the orthogonal projection of a normal line of the first circular surface to a flat plane defined by the <01-10> direction and the <0001> direction serving as a reference for the off orientation, and a normal line of the (0-33-8) plane. The sign of a positive value corresponds to a case where the orthogonal projection approaches in parallel with the <01-10> direction, whereas the sign of a negative value corresponds to a case where the orthogonal projection approaches in parallel with the <0001> direction. Further, the expression “the first circular surface having an off angle of not less than −3° and not more than +5° relative to the (0-33-8) plane in the <01-10> direction” indicates that the first circular surface corresponds to a plane, at the carbon plane side, which satisfies the above-described conditions in the silicon carbide crystal. Further, the (0-33-8) plane includes an equivalent plane, at the carbon plane side, which is expressed in a different manner due to determination of an axis for defining a crystal plane, and does not include a plane at the silicon plane side. On the other hand, the {03-38} plane includes both the (0-33-8) plane that is a carbon-side plane and the (03-38) plane that is a silicon-side plane.

### Advantageous Effects of Invention

According to the present invention, a silicon carbide substrate is provided with a first depression connecting first and second notch portions to each other, i.e., is provided with a notch for indication of a crystal orientation. An amount of processing involved in forming the notch can be smaller than an amount of processing involved in forming an orientation flat. Accordingly, a silicon carbide substrate allowing for indication of a crystal orientation can be manufactured more readily.

### BRIEF DESCRIPTION OF DRAWINGS

FIG. 1 is a perspective view schematically showing a configuration of a silicon carbide substrate in a first embodiment.

FIG. 2 is a schematic plan view of the silicon carbide substrate of FIG. 1.

FIG. 3 is a schematic bottom view of the silicon carbide substrate of FIG. 1.

FIG. 4 is a schematic front view of the silicon carbide substrate of FIG. 1.

FIG. 5 is a perspective view schematically showing a first step of a method for manufacturing the silicon carbide substrate in the first embodiment.

FIG. 6 is a perspective view schematically showing a second step of the method for manufacturing the silicon carbide substrate in the first embodiment.

FIG. 7 is a perspective view schematically showing a third step of the method for manufacturing the silicon carbide substrate in the first embodiment.

FIG. 8 is a perspective view schematically showing a fourth step of the method for manufacturing the silicon carbide substrate in the first embodiment.

FIG. 9 is a perspective view schematically showing a fifth step of the method for manufacturing the silicon carbide substrate in the first embodiment.

FIG. 10 is a front view schematically showing a configuration of a silicon carbide substrate in a variation of the first embodiment.

FIG. 11 is a plan view schematically showing a configuration of a silicon carbide substrate in a second embodiment.

FIG. 12 is a schematic bottom view of the silicon carbide substrate of FIG. 11.

FIG. 13 schematically shows that the silicon carbide substrate of FIG. 11 is turned over around an axis AXm.

FIG. 14 is a plan view schematically showing a configuration of a silicon carbide substrate in a third embodiment.

FIG. 15 is a schematic bottom view of the silicon carbide substrate of FIG. 14.

FIG. 16 schematically shows that the silicon carbide substrate of FIG. 14 is turned over around an axis AXc.

FIG. 17 is a plan view schematically showing a configuration of a silicon carbide substrate in a fourth embodiment.

FIG. 18 is a schematic bottom view of the silicon carbide substrate of FIG. 17.

FIG. 19 is a schematic partial cross sectional view taken along a line XIX-XIX in FIG. 17.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

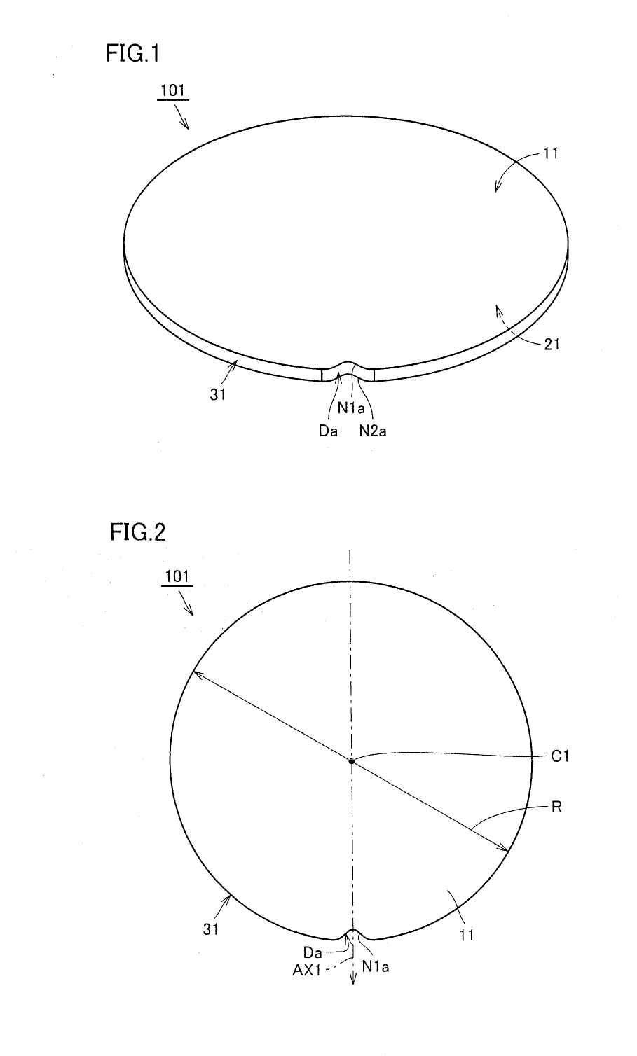

As shown in FIG. 1-FIG. 4, a silicon carbide substrate 101 of the present embodiment has a single-crystal structure, and has a first circular surface 11, a second circular surface 21, and a side surface 31. First circular surface 11 has a first center Cl and a first notch portion N1a. Second circular surface 21, which is opposite to first circular surface 11, has a second center C2 and a second notch portion N2a. The shape (first shape) of first notch portion N1a and the shape (second shape) of second notch portion N2a are the same. First notch portion N1a and second notch portion N2a are opposite to each other in the thickness direction of silicon carbide substrate 101. Side surface 31 connects first circular surface 11 and second circular surface 21 to each other. Further, side surface 31 has a first depression Da connecting first notch portion N1a and second notch portion N2a to each other. First depression Da is constituted by a surface parallel to the thickness direction of silicon carbide substrate 101. Further, first circular surface 11 and second circular surface 21 respectively have shapes obtained by forming first notch portion N1a and second notch portion N2a in circles each having a diameter R.

The following describes a method for manufacturing silicon carbide substrate 101.

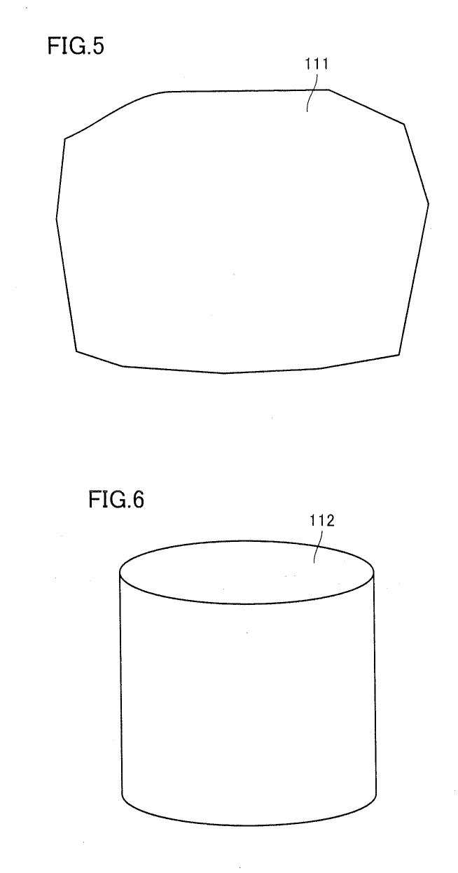

As shown in FIG. 5 and FIG. 6, an ingot 111 formed from silicon carbide having a single-crystal structure is prepared. Ingot 111 is shaped to obtain an ingot 112 having a cylindrical shape.

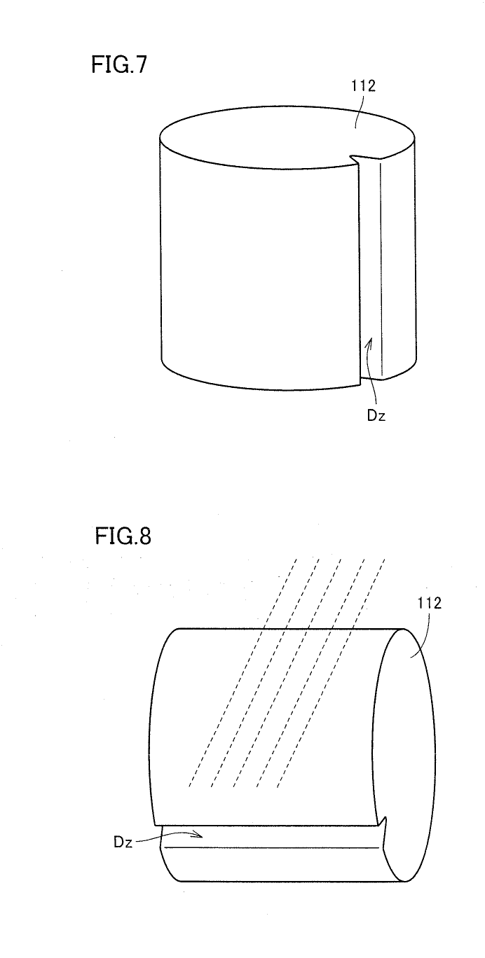

As shown in FIG. 7, a provisional notch Dz is formed in a specific orientation at the side surface of ingot 112 thus having the cylindrical shape. This specific orientation corresponds to an orientation in which first depression Da is to be formed, and can be specified using, for example, X ray. Further, provisional notch Dz can be formed using a device such as a grinder.

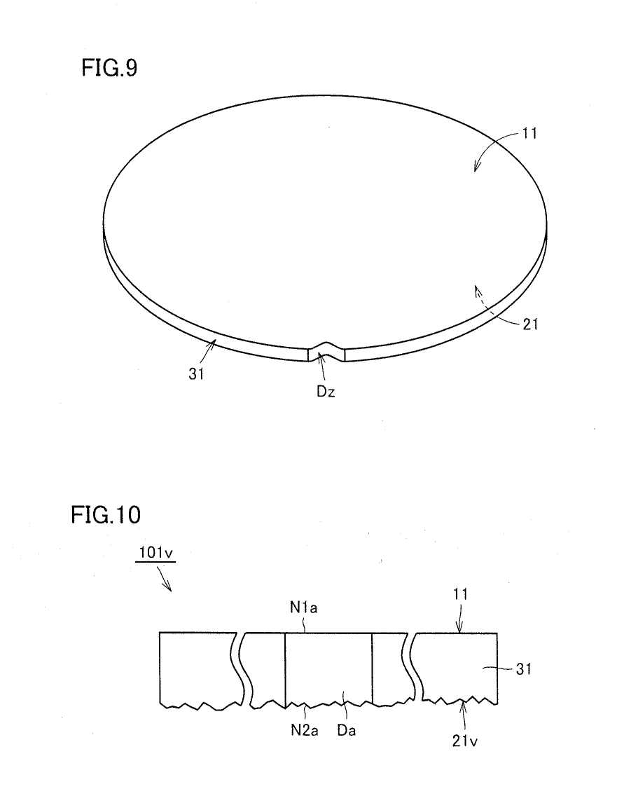

As shown in FIG. 8 and FIG. 9, ingot 112 is sliced as indicated by broken lines in the figure, thereby obtaining a silicon carbide substrate having provisional notch Dz, first circular surface 11, and second circular surface 12. Next, the region having provisional notch Dz formed therein is further grinded and polished. Accordingly, first depression Da (FIG. 1) is formed. Next, first circular surface 11 and second circular surface 12 are polished. Accordingly, silicon carbide substrate 101 (FIG. 1) is obtained.

According to the present embodiment, silicon carbide substrate 101 is provided with first depression Da connecting first notch portion N1a and second notch portion N2a to each other, i.e., provided with a notch for indication of the crystal orientation of silicon carbide substrate 101. An amount of processing involved in forming this notch can be smaller than an amount of processing involved in forming an orientation flat. Accordingly, a silicon carbide substrate allowing for indication of a crystal orientation thereof can be manufactured more readily.

Preferably, diameter R is 15 cm or greater. Most of manufacturing devices and inspection devices handling silicon substrates each having a diameter of 15 cm or greater accommodate to substrates having notches rather than orientation flats. According to the present embodiment, such manufacturing devices and inspection devices can be used to deal with the silicon carbide substrate.

Preferably, each of first notch portion N1a and second notch portion N2a is formed to have a rounded portion. This prevents generation of cracks during the formation of the notch, as compared with a case where a sharp edge is formed at each of first notch portion N1a and second notch portion N2a. Preferably, the rounded portion has a curvature radius of 0.1 mm or greater, thereby preventing occurrence of chipping. The shape of each of first notch portion N1a and second notch portion N2a is, for example, a semielliptical shape or a triangular shape having rounded apexes.

Further, the size of each of first notch portion N1a and second notch portion N2a in the radial direction of silicon carbide substrate 101 is preferably not less than 0.5 mm and not more than 5 mm. When this size is 0.5 mm or greater, first notch portion N1a and second notch portion N2a can be readily distinguished from a mere chipping. On the other hand, when the size is 5 mm or smaller, there can be reduced an amount of grinding required to form first depression Da connecting first notch portion N1a and second notch portion N2a.

It is preferable for silicon carbide substrate 101 to have a small crystal defect density. This prevents generation of cracks. Preferably, silicon carbide substrate 101 has a micro pipe density of not more than 10/cm² and has an etch-pit density of not less than 10000/cm².

Further, the generation of cracks is prevented more as warpage of silicon carbide substrate 101 is smaller. Preferably, silicon carbide substrate 101 has a warpage of 30 μm or smaller.

Preferably, the above-described single-crystal structure has hexagonal crystal, and first notch portion N1a is positioned on an orthogonal projection AX1, to first circular surface 11, of an axis extending from first center C1 in one of the <11-20> direction and the <1-100> direction. In this way, the <11-20> direction or the <1-100> direction can be readily recognized which have features in carrier mobility.

Preferably, the crystal structure of silicon carbide substrate 101 and the plane orientation of first circular surface 11 are selected to achieve large carrier mobility (channel mobility). Specifically, the single-crystal structure of silicon carbide substrate 101 has hexagonal crystal and first circular surface 11 has an off angle of not less than 50° and not more than 65° relative to the {0001} plane. More preferably, either a first condition or a second condition described below is satisfied.

The first condition is such that the off angle has an off orientation falling within a range of ±5° or smaller relative to the <01-10> direction. Preferably, first circular surface 11 has an off angle of not less than −3° and not more than +5° relative to the {03-38} plane in the <01-10> direction. More preferably, first circular surface 11 has an off angle of not less than −3° and not more than +5° relative to the (0-33-8) plane in the <01-10> direction.

The second condition is preferably such that the off angle has an off orientation falling within a range of ±5° or smaller relative to the <11-20> direction.

Referring to FIG. 10, a variation of the present embodiment will be described.

A silicon carbide substrate 101v of the present variation has a second circular surface 21v instead of second circular surface 21 (FIG. 4). First circular surface 11 has a surface roughness different from that of second circular surface 21v. Preferably, they are different from each other to such an extent that the difference can be recognized by visual observation. Specifically, first circular surface 11 has a surface roughness Ra less than 10 nm, and second circular surface 21v has a surface roughness Ra equal to or greater than 10 nm. For example, first circular surface 11 is polished to be a mirror surface, whereas second circular surface 21 is left with a scratch recognizable by visual observation.

According to the present variation, first circular surface 11 and second circular surface 12v of silicon carbide substrate 101 can be distinguished from each other by the difference in surface roughness therebetween. First circular surface 11 and the second circular surface have different properties due to characteristics of the crystal structure of the silicon carbide. Hence, it is particularly useful to distinguish them from each other, when the substrate is made of single-crystal silicon carbide. For example, in the case where silicon carbide substrate 101 is formed by slicing in parallel with the {0001} plane, one of first circular surface 11 and second circular surface 21 corresponds to the Si (silicon) plane and the other corresponds to the C (carbon) plane. Thus, first circular surface 11 and second circular surface 21 have physical properties different from each other. Hence, it is important to distinguish first circular surface 11 and second circular surface 21 from each other.

### Second Embodiment

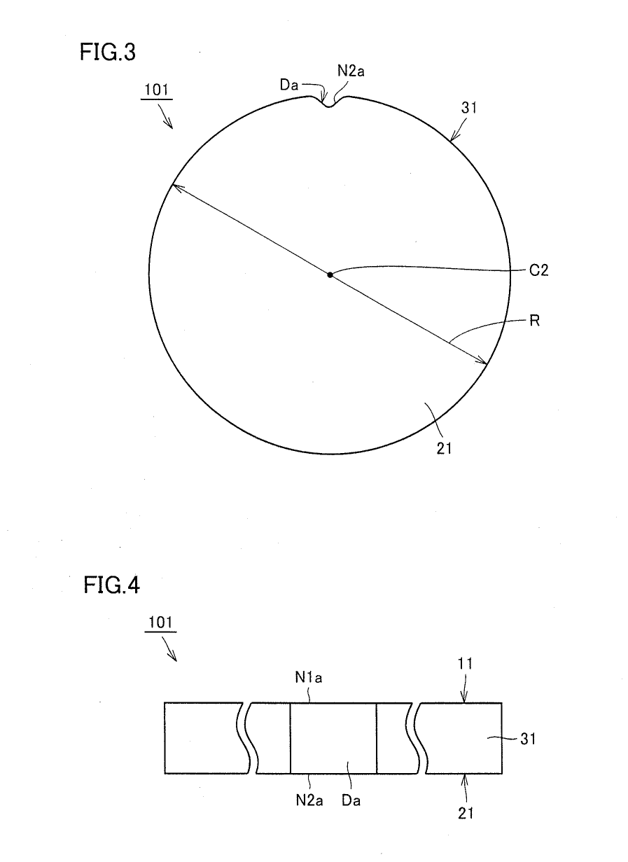

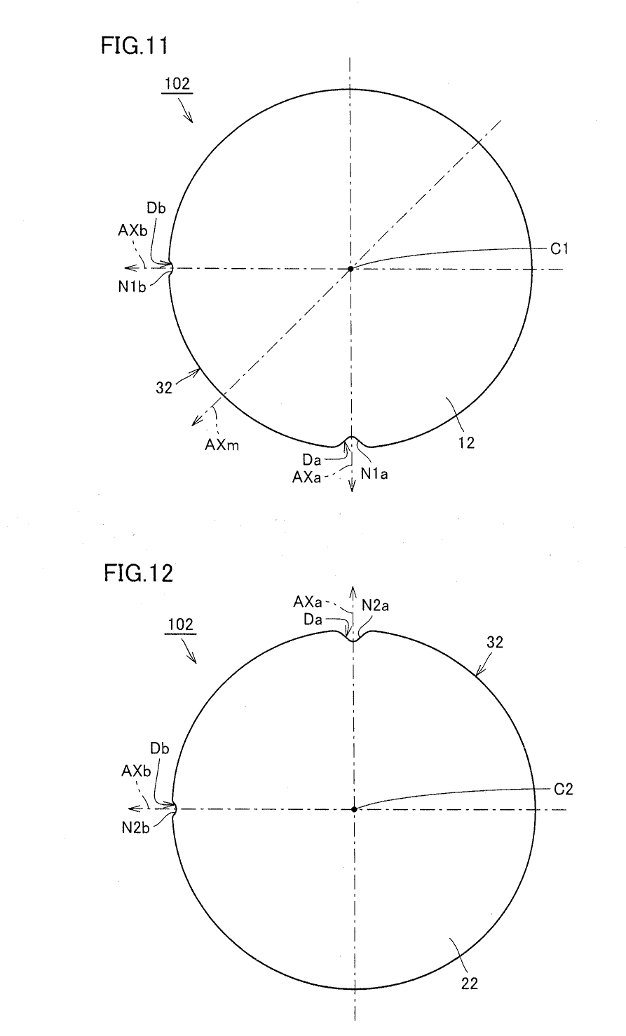

As shown in FIG. 11 and FIG. 12, a silicon carbide substrate 102 of the present embodiment has a single-crystal structure, and has a first circular surface 12, a second circular surface 22, and a side surface 32. First circular surface 12 has a configuration obtained by further providing a third notch portion N1b in first circular surface 11 (FIG. 2). Second circular surface 22 has a configuration obtained by further providing a fourth notch portion N2b in second circular surface 21 (FIG. 3). Third notch portion N1b and fourth notch portion N2b are opposite to each other in the thickness direction. The shape (third shape) of third notch portion N1b and the shape (fourth shape) of fourth notch portion N2b are the same. The third shape is different from the shape (first shape) of first notch portion N1a, and the fourth shape is different from the shape (second shape) of second notch portion N2a. In the present embodiment, the third and fourth shapes are the same. Side surface 32 has a configuration obtained by further providing a second depression Db in side surface 31 (FIG. 1). Second depression Db connects third notch portion N1b and fourth notch portion N2b to each other.

As shown in FIG. 11, a first notch axis AXa is an imaginary axis extending through first center C1 and first notch portion N1a when viewed in a planar view. Second notch axis AXb is an imaginary axis extending through first center C1 and third notch portion n1b when viewed in a planar view. First notch axis AXa and second notch axis AXb are crossed with each other at first center C1. An axis AXm extends through first center C1 when viewed in a planar view and has an exactly intermediate orientation between the orientation of first notch axis AXa and the orientation of second notch axis AXb.

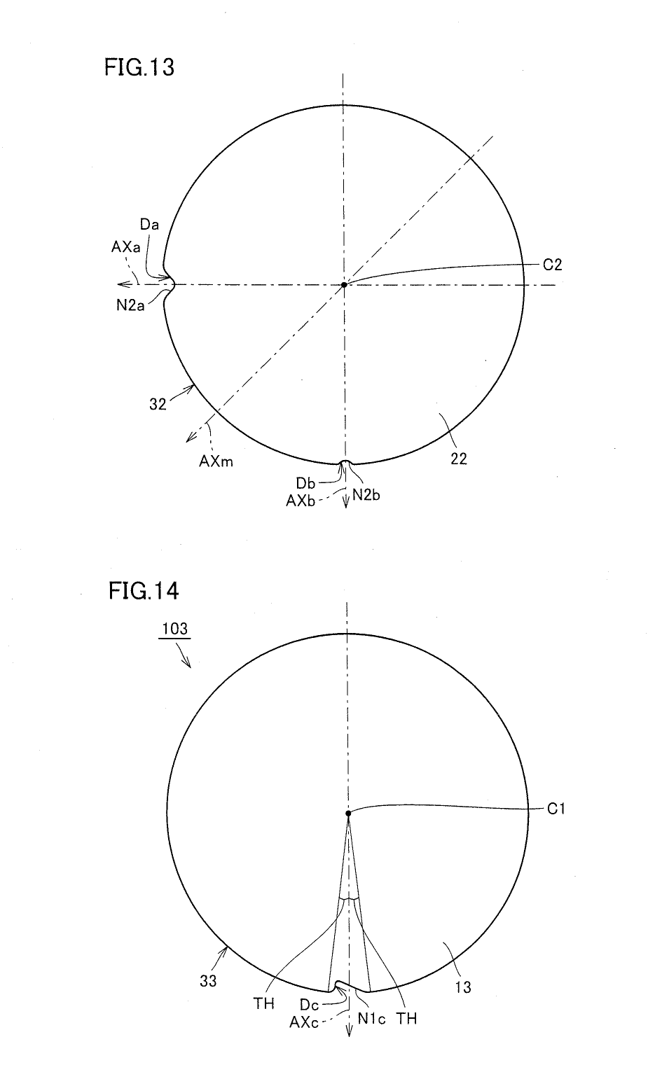

When silicon carbide substrate 102 shown in FIG. 11 is turned over around axis AXm, silicon carbide substrate 102 is brought into a state shown in FIG. 13. As understood from comparison between FIG. 11 and FIG. 13, silicon carbide substrate 102 has asymmetry for this turnover. Specifically, when the position of first depression Da and the position of second depression Db are interchanged by this turnover, for example, the shape of the notch portion located in a clockwise direction relative to axis AXm is changed from the third shape (FIG. 11: the shape of third notch portion N1b) to the second shape (FIG. 13: the shape of second notch portion N2a). Because both the shapes are different from each other as described above, the state of FIG. 11 and the state of FIG. 13, i.e., the state in which first circular surface 12 is exposed and the state in which the second circular surface 22 is exposed can be distinguished from each other. It should be noted that silicon carbide substrate 102 also has asymmetry for turnover around an axis other than axis AXm.

First circular surface 11 and the second circular surface have different properties resulting from characteristics of the crystal structure of silicon carbide. Hence, it is particularly useful to distinguish them from each other, when the substrate is made of single-crystal silicon carbide. For example, in the case where silicon carbide substrate 101 is formed by slicing in parallel with the {0001} plane, one of first circular surface 11 and second circular surface 21 corresponds to the Si plane and the other corresponds to the C plane. Accordingly, first circular surface 11 and second circular surface 21 have different physical properties. In other words, according to the present embodiment, first circular surface 11 and second circular surface 21 thus having different physical properties can be distinguished from each other.

### Third Embodiment

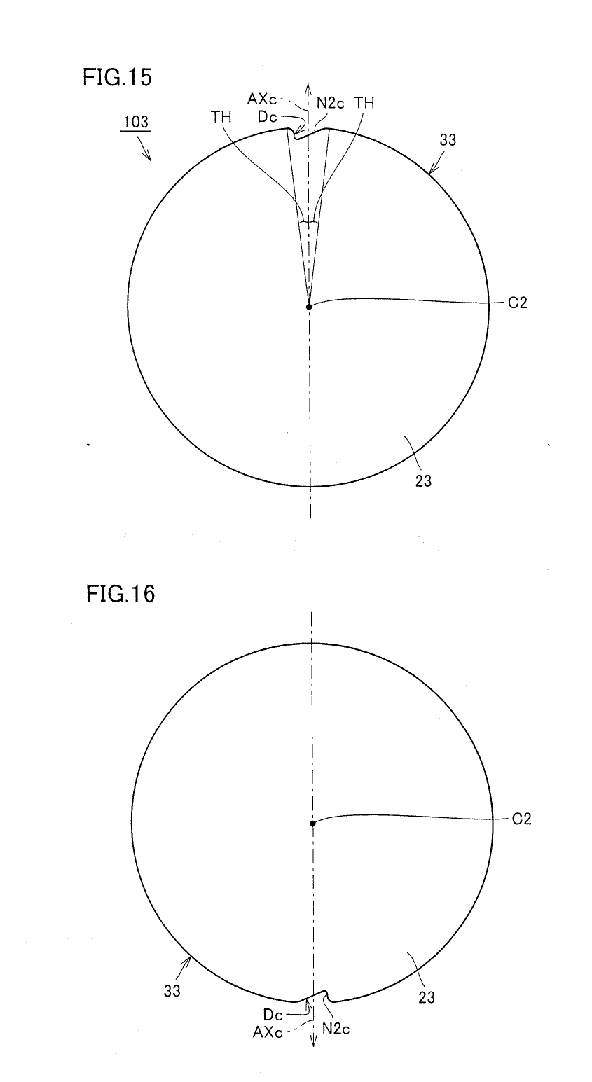

As shown in FIG. 14 and FIG. 15, a silicon carbide substrate 103 of the present embodiment has a single-crystal structure, and has a first circular surface 13, a second circular surface 23, and a side surface 33. First circular surface 13 has a first center C1 and a first notch portion N1c. Second circular surface 21, which is opposite to first circular surface 13, has a second center C2 and a second notch portion N2c. First notch portion N1c and second notch portion N2c are opposite to each other in the thickness direction. Side surface 33 connects first circular surface 13 and second circular surface 23 to each other. Further, side surface 33 has a first depression Dc connecting first notch portion N1c and second notch portion N2c to each other. First depression Dc is constituted by a surface parallel to the thickness direction of silicon carbide substrate 103. Further, each of first circular surface 13 and second circular surface 23 has a diameter R.

An axis AXc (FIG. 14) is an imaginary axis extending through first center C1 and first notch portion N1c when viewed in a planar view. More specifically, when viewed in a planar view, axis AXc extends to divide, into two angles TH, the central angle of a sector, which is defined by an arc where first notch portion N1c is formed in the circumference of a circle corresponding to side surface 33. The shape (first shape) of first notch portion N1c and the shape (second shape) of second notch portion N2c are the same. The shape of first notch portion N1c is not line-symmetric relative to axis AXc when viewed in a planar view (FIG. 14). Hence, the shape of second notch portion N2c is not line-symmetric relative to axis AXc when viewed in a planar view (FIG. 15). In other words, each of the shapes of first notch portion N1c and second notch portion N2c has asymmetry for turnover thereof.

When silicon carbide substrate 103 is turned over around axis AXc, silicon carbide substrate 103 is brought into the state shown in FIG. 16. As understood from comparison between FIG. 14 and FIG. 16, silicon carbide substrate 103 has asymmetry for this turnover. Specifically, this turnover brings about change of the shape of the notch portion when viewed in a planar view. This makes it possible to distinguish the state shown in FIG. 14 and the state shown in FIG. 16 from each other, i.e., distinguish the state in which first circular surface 13 is exposed and the state in which second circular surface 23 is exposed from each other. It should be noted that silicon carbide substrate 103 has also asymmetry for turnover around an axis other than axis AXc.

According to the present embodiment, using only one notch (first depression Dc), first circular surface 13 and second circular surface 23 can be distinguished from each other as with the second embodiment.

### Fourth Embodiment

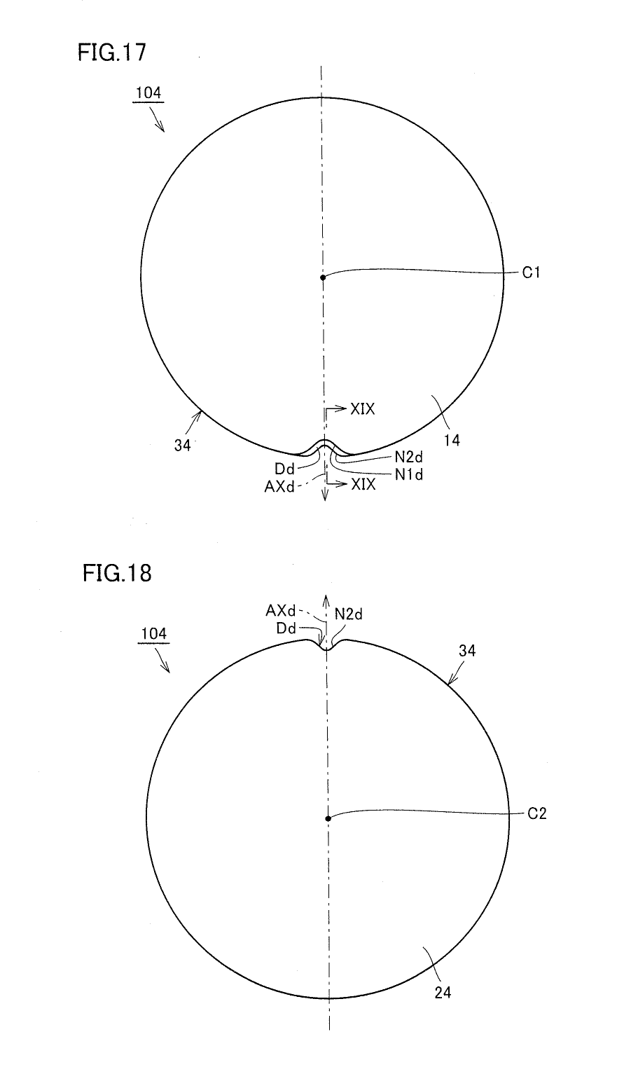

As shown in FIG. 17 and FIG. 18, a silicon carbide substrate 104 of the present embodiment has a single-crystal structure, and has a first circular surface 14, a second circular surface 24, and a side surface 34. First circular surface 14 has a first center C1 and a first notch portion N1d. Second circular surface 24, which is opposite to first circular surface 14, has a second center C2 and a second notch portion N2d. First notch portion N1d and second notch portion N2d are opposite to each other in the thickness direction. Side surface 34 connects first circular surface 14 and second circular surface 24 to each other. Further, side surface 34 has a first depression Dd connecting first notch portion N1d and second notch portion N2d. Further, each of first circular surface 14 and second circular surface 24 has a diameter R.

The shape (first shape) of first notch portion N1d and the shape of second notch portion N2d (second notch portion) are different from each other. Accordingly, first depression Dd has a portion inclined relative to the thickness direction of silicon carbide substrate 104.

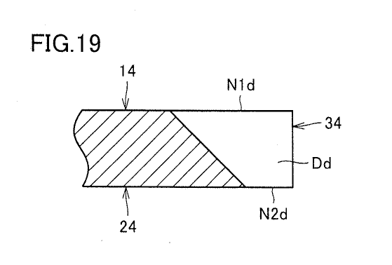

An axis AXd (FIG. 17) is an imaginary axis extending through first center C1 and first notch portion N1d when viewed in a planar view. Because the shape of first notch portion N1d and the shape of second notch portion N2d are different from each other as described above, first depression Dd has asymmetry for turnover around axis AXd. Specifically, the cross sectional shape shown in FIG. 19 becomes upside down by this turnover. Hence, silicon carbide substrate 104 has asymmetry. In other words, because the shape of first notch portion N1d and the shape of second notch portion N2d are different from each other, silicon carbide substrate 104 has asymmetry for the turnover.

The present embodiment also provides a function and an effect similar to those of the third embodiment by the above-described asymmetry. Unlike the third embodiment, the shape of first notch portion N1d may be line-symmetric to axis AXd.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

101-104, 101v: silicon carbide substrate; 11-14: first circular surface; 21-24, 21v: second circular surface; 31-34: side surface.

1. A silicon carbide substrate having a single-crystal structure, comprising:
a first circular surface provided with a first notch portion;
a second circular surface opposite to said first circular surface and provided with a second notch portion; and
a side surface connecting said first and second circular surfaces to each other, said first and second notch portions being opposite to each other, said side surface having a first depression connecting said first and second notch portions to each other.

2. The silicon carbide substrate according to claim 1, wherein the silicon carbide substrate has asymmetry for given turnover of the silicon carbide substrate.

3. The silicon carbide substrate according to claim 2, wherein:
said first circular surface includes a third notch portion having a shape different from that of said first notch portion,
said second circular surface includes a fourth notch portion having a shape different from that of said second notch portion, said third and fourth notch portions being opposite to each other, and
said side surface has a second depression connecting said third and fourth notch portions to each other.

4. The silicon carbide substrate according to claim 2, wherein said first depression has asymmetry for said turnover.

5. The silicon carbide substrate according to claim 2, wherein shapes of said first and second notch portions are different from each other.

6. The silicon carbide substrate according to claim 2, wherein shapes of said first and second notch portions are the same and have asymmetry for said turnover.

7. The silicon carbide substrate according to claim 1, wherein said first circular surface has a surface roughness different from that of said second circular surface.

8. The silicon carbide substrate according to claim 7, wherein one of said first and second circular surfaces has a surface roughness Ra less than 10 nm and the other thereof has a surface roughness Ra equal to or greater than 10 nm.

9. The silicon carbide substrate according to claim 1, wherein each of said first and second circular surfaces has a diameter equal to or greater than 15 cm.

10. The silicon carbide substrate according to claim 1, wherein:
said single-crystal structure has hexagonal crystal, and
said first notch portion is positioned on an orthogonal projection, to said first circular surface, of an axis extending from a center of said first circular surface in one of a <11-20> direction and a <1-100> direction.

11. The silicon carbide substrate according to claim 1, wherein the silicon carbide substrate has a micro pipe density of 10/cm² or smaller.

12. The silicon carbide substrate according to claim 1, wherein the silicon carbide substrate has an etch-pit density of 10000/cm² or smaller.

13. The silicon carbide substrate according to claim 1, wherein the silicon carbide substrate has a warpage of 30 μm or smaller.

14. The silicon carbide substrate according to claim 1, wherein:
said single-crystal structure has hexagonal crystal, and
said first circular surface has an off angle of not less than 50° and not more than 65° relative to a {0001} plane.

15. The silicon carbide substrate according to claim 14 , wherein said off angle has an off orientation falling with a range of ±5° or smaller relative to a <01-10> direction.

16. The silicon carbide substrate according to claim 15, wherein said first circular surface has an off angle of not less than −3° and not more than +5° relative to a {03-38} plane in the <01-10> direction.

17. The silicon carbide substrate according to claim 16, wherein said first circular surface has an off angle of not less than −3° and not more than +5° relative to a (0-33-8) plane in the <01-10> direction.

18. The silicon carbide substrate according to claim 14, wherein said off angle has an off orientation falling within a range of ±5° or smaller relative to a <11-20> direction.
